(19) United States
(12) Patent Application Publication
(10) Pub. No.: US 2026/0252256 A1
(43) Pub. Date: Aug. 27, 2026

(54) SRAM REPAIR CIRCUIT

(71) Applicant: Shanghai Huali Integrated Circuit Corporation, Shanghai (CN)

(72) Inventors: Mu CAO, Shanghai (CN); Liang HONG, Shanghai (CN); Wen LIU, Shanghai (CN)

(21) Appl. No.: 19/538,616

(22) Filed: Feb. 12, 2026

(30) Foreign Application Priority Data
Feb. 25, 2025 (CN) 202510214671.6

(51) Int. Cl. G06F 3/06

(52) U.S. Cl. CPC G06F 3/0653; G06F 3/0614; G06F 3/0673

(57) ABSTRACT

This application discloses a static random access memory (SRAM) repair circuit including a row redundancy array module, a built-in self-test (BIST) module, a repair address mapping module, and a repair address control module. The BIST module is configured to detect failed cells and output failing addresses. The repair address mapping module is configured to register each of the failing addresses and provide a first enable signal. The repair address mapping module controls turning on and turning off of the repair function through the first enable signal and obtains address mapping through the failing address. The repair address control module is configured to control strobing and turning off of each of the redundancy memory rows of the row redundancy array module through a second enable signal and a repair row selection signal when the repair function is turned on.

### CROSS-REFERENCES TO RELATED APPLICATIONS

This application claims priority to Chinese patent application No. 202510214671.6, filed on February 25, 2025, the disclosure of which is incorporated herein by reference in its entirety.

### TECHNICAL FIELD

This application relates to the field of semiconductor integrated circuits, and in particular, to a static random access memory (SRAM) repair circuit.

### BACKGROUND

Bitcells in a static random access memory (SRAM) have a small feature size and a difficult process and are prone to defects. A memory array composed of the bitcells has a large area and high defect sensitivity. A failure of one bitcell may lead to a functional failure of an entire SRAM intellectual property (IP) module.

In fields such as microprogrammed control unit (MCU), Bluetooth, intelligent voice, display driving, image processing, the SRAM is a high demand for a system. The area ratio of the SRAM in a system chip continues to increase. Especially in the field of display driving, the capacity of the SRAM has reached tens of megabits or more. The failure of the bitcell may lead to a serious yield loss of a chip. Therefore, the repair technology for the SRAM is increasingly important. The principle thereof is as follows: a redundancy array region is arranged in SRAM IP, a failed cell in a normal memory array is detected through build_in_self_test (BIST), and the failed cell is replaced with a redundancy region cell through address mapping to achieve a repair purpose.

With the development of process nodes, the ratio of the SRAM in a chip continues to increase. A failure mechanism of a bitcell is becoming increasingly complex. Especially in the early stage of process development, a situation where a plurality of bitcells fail simultaneously often occurs in SRAM IP. For a yield of a product, a plurality of repairs by the repair function of SRAM are required.

### BRIEF SUMMARY

According to some embodiments in this application, a SRAM repair circuit disclosed in this application comprising: a row redundancy array module, a built-in self-test (BIST) module, a repair address mapping module, and a repair address control module.

The row redundancy array module includes a plurality of redundancy memory rows, and a structure of each of the redundancy memory rows is the same as a structure of each of the memory rows in a memory array of an SRAM.

The BIST module is configured to detect whether the memory array has failed cells and output failing addresses , i.e. repair address (RA), corresponding to the failed cells when the failed cells are present.

The repair address mapping module is configured to register each of the failing addresses, provide a first enable signal, and achieve controlling of turning on of a repair function and control address mapping.

The repair address mapping module controls turning on and turning off of the repair function through the first enable signal and obtains the address mapping through the failing address. The first enable signal includes a plurality of bits. The repair function is turned off when each of the signal bits of the first enable signal is disabled.

The repair address mapping module compares a read-write operation address and the failing address when at least one signal bit of the first enable signal is enabled, maps a read-write operation to the row redundancy array module when the read-write operation address and the failing address are the same to turn on the repair function, and maps the read-write operation to the memory array when the read-write operation address and the failing address are different.

The repair address control module is configured to control strobing and turning off of each of the redundancy memory rows of the row redundancy array module through a second enable signal and a repair row selection signal when the repair function is turned on.

In some cases,the quantity of signal bits of the second enable signal is the same as the quantity of signal bits of the repair row selection signal.

Signal bits of the second enable signal and signal bits of the repair row selection signal having the same bit sequence numbers form a repair address control signal set. The repair address control signal set controls strobing and turning off of one of the redundancy memory rows.

The second enable signal is obtained through the first enable signal.

One failing address corresponds to a signal bit of one repair row selection signal.

When a signal bit of the second enable signal of the repair address control signal set is enabled, and when the read-write operation address and a corresponding failing address are the same, a signal bit of the repair row selection signal of the repair address control signal set is switched to a strobing level and enables a controlled redundancy memory row to be strobed.

In some cases,one failing address corresponds to a signal bit of one first enable signal.

When the BIST module detects the failing address, a signal bit of the first enable signal corresponding to the failing address is enabled.

In some cases,a repair function fool-proof protection module is further included.

The repair function fool-proof protection module is configured to provide a third enable signal. The third enable signal is connected to a word line decoding module.

When the repair row selection signal selects at least one of the redundancy memory rows, the third enable signal is enabled and causes the word line decoding module to be turned off.

In some cases,the repair row selection signal is connected to a repair word line of each of the redundancy memory rows through a repair word line module.

The repair function fool-proof protection module is further configured to provide a fourth enable signal. The fourth enable signal is connected to the repair word line module.

When the repair row selection signal selects more than two of the redundancy memory rows, the fourth enable signal is enabled and causes the repair word line module to be turned off.

In some cases,the repair function fool-proof protection module is further configured to provide a fifth enable signal.

The fifth enable signal is connected to a column multiplexer (column_mux). The fifth enable signal causes the column multiplexer to be turned off when the repair row selection signal selects more than two of the redundancy memory rows.

In some cases,the repair function fool-proof protection module is further configured to provide a sixth enable signal.

The sixth enable signal is connected to a sense amplifier (SA). The sixth enable signal causes the sense amplifier to be turned off when the repair row selection signal selects more than two of the redundancy memory rows.

In some cases,the repair address control module further outputs a seventh enable signal, the seventh enable signal is connected to the repair function fool-proof protection module, and when the repair function is turned on,the seventh enable signal activates the repair function fool-proof protection module.

In some cases,the quantity of bits of the repair row selection signal is the same as the quantity of rows of the redundancy memory row, and bits of the repair row selection signal correspond to the redundancy memory rows one by one.

In some cases,the repair address mapping module further includes a function of performing repeatability detection on the failing address.

The repeatability detection includes: during the k-th repair, the repair address mapping module determines whether a failing address for the k-th repair is the same as each of failing addresses of previous k-1 repairs. If a case that they are identical exists, a signal bit of a first enable signal corresponding to the failing address for the k-th repair kept being disabled. If a case that they are identical does not exist, the signal bit of the first enable signal corresponding to the failing address for the k-th repair keeps being enabled. k is a quantity of rows greater than 1 and less than or equal to the redundancy memory rows.

In some cases,when the signal bit of the first enable signal is enabled, a signal bit corresponding to the second enable signal is also enabled. When the signal bit of the first enable signal is disabled, the signal bit corresponding to the second enable signal is also disabled.

The second enable signal is connected to the repair word line module.

When the signal bit of the second enable signal of the repair address control signal set is enabled, a signal bit of the repair row selection signal of the repair address control signal set is connected to a corresponding repair word line.

When the signal bit of the second enable signal of the repair address control signal set is disabled, the signal bit of the repair row selection signal of the repair address control signal set is disconnected from a corresponding repair word line.

In some cases,the failing address is an address of the failed cell. The repair address mapping module uses a row address of the read-write operation address for comparison with the failing address when comparing the read-write operation address with the failing address. For the repair, a by-word repair is adopted.

Alternatively, the failing address is an entire address of the failed cell. The repair address mapping module uses an entire address of the read-write operation address for comparison with the failing address when comparing the read-write operation address with the failing address. For the repair, a by-word repair is adopted.

In some cases,the strobing level is high and the non-strobing level is low, or the strobing level is low and the non-strobing level is high.

In some cases,the signal bit of the first enable signal is enabled at a high level and disabled at a low level; or, the signal bit of the first enable signal is enabled at a low level and disabled at a high level.

The signal bit of the second enable signal is enabled at a high level and disabled at a low level; or, the signal bit of the second enable signal is enabled at a low level and disabled at a high level.

In some cases,the row redundancy array module is a repair data memory region within an SRAM IP.

In some cases,the BIST module tests all values covered by an addressing range of the SRAM.

The BIST module is embedded in the SRAM and as part of the SRAM IP. Or, the BIST module is mounted as a soft-core outside the SRAM IP.

In some cases,the repair address mapping module is embedded in the SRAM and is part of the SRAM IP. Or, the repair address mapping module is mounted as a soft-core outside the SRAM IP.

In this application, the repair address mapping module can achieve registering of a plurality of falling addresses, can compare a read-write operation address with a falling address during a read-write operation, and control the read-write operation to be mapped to one of a redundancy array module and a memory array based on a comparison result. Since a plurality of falling addresses are present, a plurality of repair functions can be achieved. Therefore, this application can also achieve a good repair when a plurality of failed cells are in a memory array, so that a yield of a product can be improved.

In addition, a maximum value of repair times according to this application can be equal to the quantity of redundancy memory rows in a row redundancy array module, so the repair times may be flexibly set within a design range.

### BRIEF DESCRIPTION OF THE DRAWINGS

This application is further described in detail below with reference to the accompanying drawings and specific implementations:

FIG. 1 is a schematic structural diagram of a static random access memory (SRAM) repair circuit according to an embodiment of this application;

FIG. 2 is a schematic structural diagram of an interior of SRAM IP in FIG. 1;

FIG. 3 is a simulation waveform of repair function fool-proof protection of an SRAM repair circuit according to an embodiment of this application; and

FIG. 4 is a simulation waveform in which turning on of a word line during memory organization is prevented by repair function fool-proof protection of an SRAM repair circuit according to an embodiment of this application.

### DETAILED DESCRIPTION OF THE DISCLOSURE

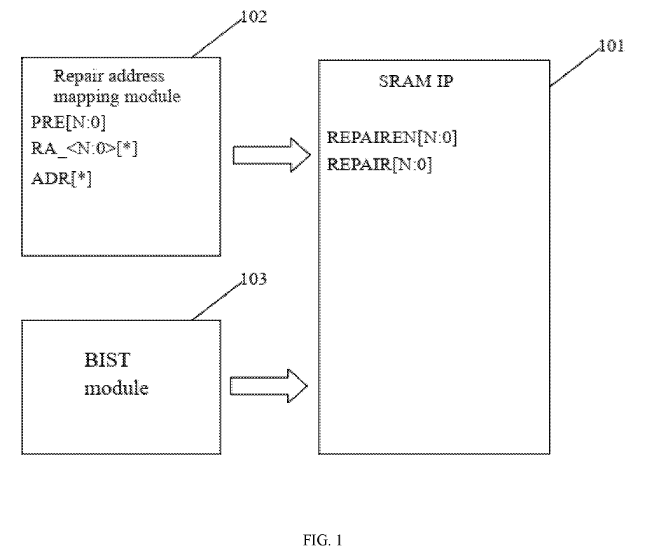

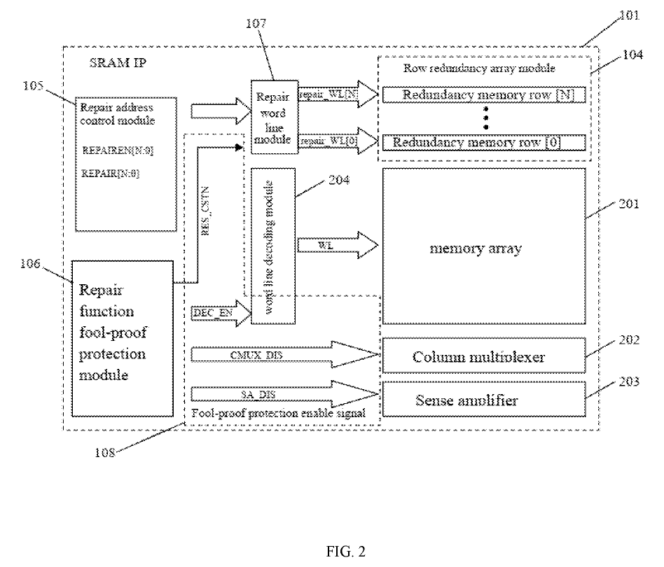

Referring to FIG. 1, FIG. 1 is a schematic structural diagram of a static random access memory (SRAM) repair circuit according to an embodiment of this application. Referring to FIG. 2, FIG. 2 is a schematic structural diagram of an interior of the SRAM IP在·101 in FIG. 1. The SRAM repair circuit according to an embodiment of this application includes:

a row redundancy array module 104, a built-in self-test (BIST) module 103, a repair address mapping module 102, and a repair address control module 105.

The row redundancy array module 104 includes a plurality of redundancy memory rows 104a. A structure of each of the redundancy memory rows 104a is the same as a structure of each of memory rows in a memory array 201 of an SRAM. In FIG. 1, the SRAM is composed of intellectual property (IP) modules. That is, the SRAM is SRAM IP101. In FIG. 2, the quantity of rows of the redundancy memory rows 104a is N+1. In FIG. 2, the redundancy memory rows 104 are numbered from 0 to N. In FIG. 2, a redundancy memory row [0] is further shown, representing the 1st redundancy memory row 104a. The number may continue to increase from 0 to N. In FIG. 2, a redundancy memory row [N] is also shown, representing the N+1th redundancy memory row 104a.

The BIST module 103 is configured to detect whether the memory array 201 has failed cells and output failing addresses RA corresponding to the failed cells when the failed cells are present. In an embodiment of this application, a plurality of failing addresses RA are included.

In an embodiment of this application, the BIST module 103 tests all values covered by an addressing range of the SRAM.

In FIG. 1, a plurality of failing addresses RA are further represented by RA_<N: 0>[*], where <N: 0> represents any one value taken in a range of 0 to N, and N+1 failing addresses RA are shared. [*] represents a multi-bit specific address value of a failing address RA. The specific address value is changed based on a practical situation, so it is represented by the sign *. Further, RA_0[*] represents the 0th failing address RA. RA_1[*] represents the 1st failing address RA, and so on. RA_N[*] represents the Nth failing address RA.

The repair address mapping module 102 is configured to register each of the failing addresses RA, provide a first enable signal PRE, and achieve controlling of turning on of a repair function and control address mapping. The repair address mapping module 102 controls turning on and turning off of the repair function through the first enable signal PRE and obtains the address mapping through the failing address RA. The first enable signal PRE includes a plurality of bits. The repair function is turned off when each of the signal bits of the first enable signal PRE is disabled. In FIG. 1, a first enable signal PRE is further represented by PRE[N: 0]. [N: 0] represents the 0-th to the N-th signal bits of the first enable signal PRE. Further, PRE[0] represents the 0th signal bit of the first enable signal PRE. PRE[1] represents the 1st signal bit of the first enable signal PRE, and so on. PRE[N] represents the Nth first enable signal PRE.

In an embodiment of this application, one failing address RA corresponds to a signal bit of one first enable signal PRE. For example, RA_0[*] corresponds to PRE[0], RA_1[*] corresponds to PRE[1], and so on. RA_N[*] corresponds to PRE[N].

When the BIST module 103 detects the failing address RA, a signal bit of the first enable signal PRE corresponding to the failing address RA is enabled.

The repair address mapping module 102 compares a read-write operation address ADR and the failing address RA when at least one signal bit of the first enable signal PRE is enabled, maps a read-write operation to the row redundancy array module 104 when the read-write operation address ADR and the failing address RA are the same to turn on the repair function, and maps the read-write operation to the memory array 201 when the read-write operation address ADR and the failing address RA are different. In FIG. 1, the read-write operation address ADR is further represented by ADR[*]. Similarly, [*] after ADR represents a multi-bit specific address value of a read-write operation address ADR. The specific address value may be changed based on a practical situation, so it is represented by the sign *.

Referring to FIG. 2, the repair address control module 105 is configured to control strobing and turning off of each of the redundancy memory rows 104a of the row redundancy array module 104 through a second enable signal REPAIREN and a repair row selection signal REPAIR when the repair function is turned on.

In an embodiment of this application, the quantity of signal bits of the second enable signal REPAIREN is the same as the quantity of signal bits of the repair row selection signal REPAIR.

In an embodiment of this application, the quantity of bits of the repair row selection signal REPAIR is the same as the quantity of rows of the redundancy memory row 104a, and bits of the repair row selection signal REPAIR correspond to the redundancy memory rows 104a one by one.

In FIG. 2, the second enable signal REPAIREN is further represented by REPAIREN [N: 0]. [N: 0] represents the 0-th to N-th signal bits of the second enable signal REPAIREN. N+1 signal bits can be represented as REPAIREN[0], REPAIREN[1] to REPAIREN[N], respectively. The repair row selection signal REPAIR is further represented by REPAIR [N: 0]. [N: 0] represents the 0-th to N-th signal bits of the repair row selection signal REPAIR. N+1 signal bits can be represented as REPAIR[0], REPAIR [1] to REPAIR[N], respectively.

Signal bits of the second enable signal REPAIREN and signal bits of the repair row selection signal REPAIR having the same bit sequence numbers form a repair address control signal set. The repair address control signal set controls strobing and turning off of one of the redundancy memory rows 104a. Referring to FIG. 2, a repair address control signal set consisting of REPAIR[0] and REPAIREN[0] controls strobing and turning off of a redundancy memory row [0], and so on. A repair address control signal set consisting of REPAIR[N] and REPAIREN[N] controls strobing and turning off of a redundancy memory row [N].

The second enable signal REPAIREN is obtained through the first enable signal PRE.

When the signal bit of the first enable signal PRE is enabled, a signal bit corresponding to the second enable signal REPAIREN is also enabled. When the signal bit of the first enable signal is disabled, the signal bit corresponding to the second enable signal REPAIREN is also disabled.

In an embodiment of this application, the signal bit of the first enable signal PRE is enabled at a high level and disabled at a low level. Alternatively, in other embodiments, the signal bit of the first enable signal PRE is enabled at a low level and disabled at a high level.

In an embodiment of this application, the signal bit of the second enable signal REPAIREN is enabled at a high level and disabled at a low level. Alternatively, in other embodiments, the signal bit of the second enable signal REPAIREN is enabled at a low level and disabled at a high level.

One failing address RA corresponds to a signal bit of one repair row selection signal REPAIR. That is, RA_0[*] corresponds to REPAIR[0], RA_1[*] corresponds to REPAIR[1], and so on. RA_N[*] corresponds to REPAIR[N].

When a signal bit of the second enable signal REPAIREN of the repair address control signal set is enabled and when the read-write operation address ADR and a corresponding failing address RA are the same, a signal bit of the repair row selection signal REPAIR of the repair address control signal set is switched to a strobing level and enables a controlled redundancy memory row 104a to be strobed. For example, when REPAIREN[0] is enabled, the potential of REPAIR[0] may be switched to a strobing level when ADR[*] and RA_0[*] are the same, so that strobing of a redundancy memory row [0] can be controlled. Similarly, when REPAIREN[1] is enabled, the potential of REPAIR [1] may be switched to a strobing level, so that strobing of a redundancy memory row [1] can be controlled. And so on, when REPAIREN[N] is enabled, the potential of REPAIR[N] may be switched to a strobing level when ADR[*] and RA_N[*] are the same, so that strobing of a redundancy memory row [N] can be controlled.

In an embodiment of this application, a repair function fool-proof protection module 106 is further included.

The repair function fool-proof protection module 106 is configured to provide a third enable signal DEC_EN. The third enable signal DEC_EN is connected to a word line decoding module 204.

When the repair row selection signal REPAIR selects at least one of the redundancy memory rows 104a, the third enable signal DEC_EN is enabled and causes the word line decoding module 204 to be turned off. Since the word line decoding module 204 is turned off, a row address of the read-write operation address ADR is not decoded, and a specific word line WL of the memory array 201 cannot be selected. In this case, a read operation can be performed only on a selected redundancy memory row 104a, not on each memory row of the memory array 201, thereby achieving a protection function.

In an embodiment of this application, the repair row selection signal REPAIR is connected to a repair word line repair_WL of each of the redundancy memory rows 104a through a repair word line module 107. In FIG. 2, the quantity of repair word lines repair_WL corresponds to the quantity of rows of the redundancy memory rows 104, with their numbers corresponding to each other one by one. For example, repair_WL[0] represents the 0th repair word line and corresponds to a redundancy memory row [0]. repai _WL[1] represents the 1st repair word line and corresponds to a redundancy memory row [1], and so on. repair_WL[N] represents the N-th repair word line and corresponds to a redundancy memory row [N].

In an embodiment of this application, the second enable signal REPAIREN is connected to the repair word line module 107.

When a signal bit of a second enable signal REPAIREN of a repair address control signal set is enabled, a signal bit of a repair row selection signal REPAIR of the repair address control signal set is connected to a corresponding repair word line repair_WL. For example, when REPAIREN[0] is enabled, REPAIR[0] may be connected to repair_WL[0]. When the REPAIR[0] is further at a strobing level, a redundancy memory row [0] is selected. When the REPAIR[0] is at a non-strobing level, the redundancy memory row [0] is not selected. Therefore, when the REPAIREN[0] is enabled, the redundancy memory row [0] has two situations, being selected and being unselected, that are specifically determined through the level of the REPAIR[0].

When the signal bit of the second enable signal REPAIREN of the repair address control signal set is disabled, the signal bit of the repair row selection signal REPAIR of the repair address control signal set is disconnected from a corresponding repair word line repair_WL. For example, when the REPAIREN[0] is disabled, no connection is made between the REPAIR[0] and the repair_WL[0], and the redundancy memory row [0] is not selected.

In an embodiment of this application, the strobing level is a high level, and the non-strobing level is a low level. Alternatively, in another embodiment, the strobing level is a low level and the non-strobing level is a high level.

The repair function fool-proof protection module 106 is further configured to provide a fourth enable signal RES_CSTN. The fourth enable signal RES_CSTN is connected to the repair word line module 107.

When the repair row selection signal REPAIR selects more than two of the redundancy memory rows 104a, the fourth enable signal RES_CSTN is enabled and causes the repair word line module 107 to be turned off. For example, a redundancy memory row [0] is selected in a case where REPAIREN[0] is enabled and REPAIR[0] is at a strobing level, and also, a redundancy memory row [1] is selected in a case where REPAIREN[1] is enabled and REPAIR [1] is at a strobing level. This situation is not normal. In this case, only the repair word line module 107 needs to be turned off through the fourth enable signal RES_CSTN, so that the REPAIR[0] at a strobing level is prevented from being transferred to repair_WL[0] and the REPAIR[1] at a strobing level is prevented from being transferred to repair_WL[1]. Therefore, through settings of the repair word line module 107 and the fourth enable signal RES_CSTN, an abnormal situation in which more than two of the redundancy memory rows 104a are simultaneously selected can be eliminated, thereby achieving a fool-proof protection function.

In an embodiment of this application, the repair function fool-proof protection module 106 is further configured to provide a fifth enable signal CMUX_DIS.

The fifth enable signal CMUX_DIS is connected to a column multiplexer 202. The fifth enable signal CMUX_DIS causes the column multiplexer 202 to be turned off when the repair row selection signal REPAIR selects more than two of the redundancy memory rows 104a. After the column multiplexer 202 is turned off, a column address cannot be transferred to the bit line shared by the memory array 201 and the row redundancy array module 104, thereby further improving a fool-proof protection function in an abnormal case that two or more of the redundancy memory rows 104a are selected simultaneously.

The repair function fool-proof protection module 106 is further configured to provide a sixth enable signal SA_DIS.

The sixth enable signal SA_DIS is connected to a sense amplifier 203. The sixth enable signal SA_DIS causes the sense amplifier 203 to be turned off when the repair row selection signal REPAIR selects more than two of the redundancy memory rows 104a. The sensitive amplifier 203 is configured to output a read signal during a read operation, thereby further improving a fool-proof protection function in an abnormal case that two or more of the redundancy memory rows 104a are selected simultaneously.

In FIG. 2, a dashed box 108 marks all the fool-proof protection enable signals output by the repair function fool-proof protection module 106, namely, the third enable signal DEC_EN, the fourth enable signal RES_CSTN, the fifth enable signal CMUX_DIS, and the sixth enable signal SA_DIS.

In some embodiments, the repair address control module 105 further outputs a seventh enable signal (not shown). The seventh enable signal is connected to the repair function fool-proof protection module 106. When the repair function is turned on, the seventh enable signal activates the repair function fool-proof protection module 106. That is, activation of the repair function fool-proof protection module 106 is controlled through the repair address control module 105.

In an embodiment of this application, the repair address mapping module 102 further includes a function of performing repeatability detection on the failing address RA.

The repeatability detection includes: during the k-th repair, the repair address mapping module 102 determines whether a failing address RA for the k-th repair is the same as each of failing addresses RA of previous k-1 repairs. If a case that they are identical exists, a signal bit of a first enable signal PRE corresponding to the failing address RA of the k-th repair kept being disabled. If a case that they are identical does not exist, the signal bit of the first enable signal corresponding to the failing address RA of the k-th repair kept being enabled. k is a quantity of rows greater than 1 and less than or equal to the redundancy memory rows 104a. In FIG. 2, since the quantity of rows of the redundancy memory row 104a is N+1, a maximum value of k is N+1. k can be flexibly set in the range of N+1.

During a repair, a read-write operation is not performed on a failed cell corresponding to a failing address RA in a memory array 201, but is performed on a selected redundancy memory row in a row redundancy array module 104, thereby achieving a repair for the failed cell.

In an embodiment of this application, the failing address RA is an address of the failed cell. The repair address mapping module 102 uses a row address of a read-write operation address ADR for comparison with a failing address AR when comparing the read-write operation address ADR with the failing address AR. For the repair, a by-row repair is adopted. The row where the failed cell is located is replaced by a selected redundancy memory row.

Alternatively, in other embodiments, the failing address RA is an entire address of the failed cell. The repair address mapping module 102 uses an entire address of the read-write operation address ADR for comparison with the failing address RA when comparing the read-write operation address ADR with the failing address RA. For the repair, a

by-word repair is adopted. The entire address of the failed cell includes a row address and a column address. The column address can further determine the position of the failed cell in a corresponding memory row, thereby achieving a more precise repair.

In an embodiment of this application, the row redundancy array module 104 is a repair data memory region in the SRAM IP101. That is, the row redundancy array module 104 is embedded inside the SRAM.

Referring to FIG. 1, in an embodiment of this application, a BIST module 103 is mounted as a soft-core outside the SRAM IP101. Alternatively, in other embodiments, the BIST module 103 is embedded in the SRAM and is part of the SRAM IP101.

Referring to FIG. 1, in an embodiment of this application, the repair address mapping module 102 is mounted as a soft-core outside the SRAM IP101. Alternatively, in other embodiments, the repair address mapping module 102 is embedded in the SRAM and as part of the SRAM IP101.

In embodiments of this application, the repair address mapping module 102 can achieve registering of a plurality of falling addresses RA, the read-write operation address ADR can be compared with the falling address RA during a read-write operation, and the read-write operation is controlled to be mapped to one of a redundancy array module and a memory array 201 based on a comparison result. Since a plurality of falling address RA are present, a plurality of repair functions can be achieved. Therefore, the embodiments of this application can also achieve a good repair when a plurality of failed cells are in a memory array 201, so that a yield of a product can be improved.

In addition, a maximum value of repair times according to this application can be equal to the quantity of redundancy memory rows 104a in a row redundancy array module 104, so the repair times may be flexibly set within a design range.

In the embodiments of this application, a repair address control module 105 controls turning on of repair word lines repair_WL[M](M=0,1...N) of a redundancy array module, namely, a row redundancy array module 104, through a plurality of sets of repair enable signals, namely, a second enable signal REPAIREN, and a repair region row selection signal, namely, a repair row selection signal REPAIR, so as to achieve strobing and turning off of Redundancy Row, namely, a redundancy memory row [M]. In addition, a repair address control module 105 generates a fool-proof protection enable signal when a repair function is turned on and controls a repair function fool-proof protection module 106.

The repair function fool-proof protection module 106 turns off a function of a word line decoding module 204 of IP when a repair related action occurs. When a plurality of Redundancy Rows are selected simultaneously, a repair function is turned off, that is, a repair word line module 107 is turned off, and an output path of the SRAM IP is turned off simultaneously, so as to protect IP DQ output.

A BIST module 103 tests all values of addresses covered by an SRAM addressing range and feeds back results of a failure determination and a failing address. The BIST module 103 may be embedded as part of SRAM IP, or may be mounted as soft_core outside the SRAM IP.

The repair address mapping module 102 is responsible for a failing address transformation function. When a repair function is turned on, an SRAM IP REPAIR [M] (M = 0, 1... N) signal is pulled up when a read/write operation address ADR[*] is the same as a registered failing address RA_M[*] detected and fed back by a BIST module 103, and a read/write operation is mapped to a Redundancy Row [M] (M = 0, 1... N) region. If the read/write operation address ADR[*] is different from the registered failing address RA_M[*] detected and fed back by the BIST module 103, read/write is directed to a normal memory Row, namely, a memory row of a memory array 201.

To prevent a plurality of Redundancy Rows being selected simultaneously, the repair address mapping module 102 detects repeatability of a failing address RA_M[*]. During the k-th repair, first, whether RA_k[*] is the same as each of previous k-1 RA addresses is determined through detection. If a case that they are identical exists, an SRAM IP REPAIREN[k] signal is set to "0" to achieve shielding. If the case that they are identical does not exist, it is RRE[k]=REPAIREN[k]=1, and a repair action is started.

Through the comparison of the read/write operation address ADR [*] with the failing address RA_M[*] and the determination, a by-row repair may be achieved through the comparison of whether row addresses are the same, or a by-word repair may be achieved through the comparison of whether entire addresses are the same.

The repair address mapping module 102 may be embedded as part of SRAM IP, or may be mounted as soft_core outside the SRAM IP. During a repair process, a practical repair time used by a system may be flexibly set in a designed maximum number range (N).

The row redundancy array module 104 is a repair data memory region within SRAM IP, where the quantity of Rows [M] (M=0, 1... N) that may perform a repair action is equal to the quantity of sets of repair enable signals REPAIREN[M] (M=0, 1... N) and repair region row selection signals REPAIR[M] (M = 0, 1... N).

Hereinafter, an embodiment of this application is further described in conjunction with a circuit example in which an SRAM repair function may be performed for 2 times.

An SRAM capacity specification is 16Kx32, and an address bus is A[0:13], where am MUX address is A[0: 3] and a row address is A[4:13]. A repair function design includes a repair address control module 105 inside SRAM IP, a repair function fool-proof protection module 106, a Row Redundancy module, namely, a row redundancy array module 104, and a repair address mapping module 102 and a BIST module 103 that are mounted outside SRAM IP and formed through digital synthesis.

The repair address control module 105 controls turning on of word lines repair_WL[0] and repair_WL[1] of a Redundancy array module through 2 sets of repair enable signals REPAIREN[0] and REPAIREN[1] and repair region row selection signals REPAIR[0] and REPAIR[1]. A functional effect is shown in FIG. 3, and it may be seen:

In a period 302, REPAIREN[1] and REPAIR[1] are both 1, and repair_WL[1] is turned on;

in a period 303, REPAIREN[0] and REPAIR[0] are both 1, and repair_WL[0] is turned on; and

in a period 304a, both REPAIREN[0] and REPAIR[0] and REPAIREN[1] and REPAIR[1] are 0, and neither repair_WL[0] nor repair_WL[1] is turned on.

In a period 304b, although both REPAIREN[0] and REPAIREN[1] are 1, both REPAIR[0] and REPAIR[1] are 0, and neither repair_WL[0] nor repair_WL[1] is turned on.

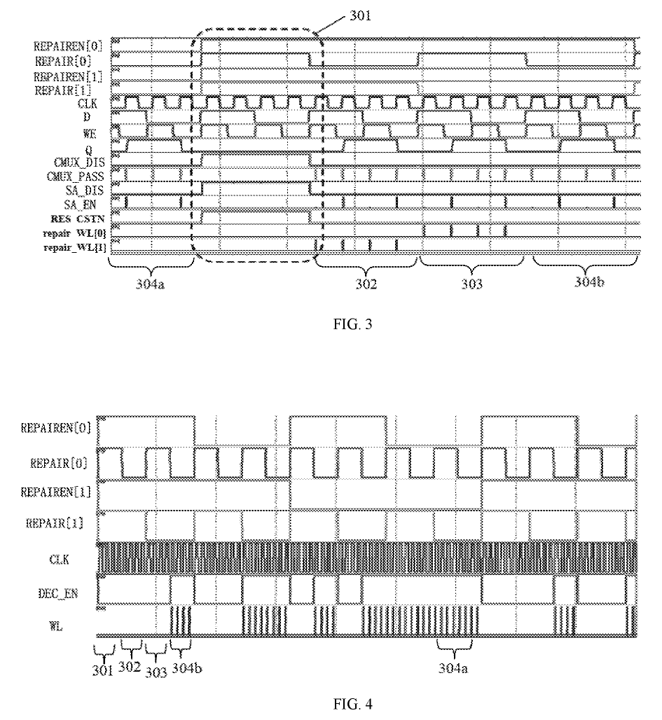

A repair function fool-proof protection module 106 turns off a function of a word line decoding module 204 of IP when any one set of REPAIREN[0] and REPAIR[0] or REPAIREN[1] and REPAIR[1] is turned on simultaneously. Referring to FIG. 4, in the period 302, both REPAIREN[1] and REPAIR[1] are 1, so that a third enable signal DEC_EN is low, and the function of the word line decoding module 204 is turned off.

In the period 303, both REPAIREN[0] and REPAIR[0] are 1, so the third enable signal DEC_EN is low, and the function of the word line decoding module 204 is turned off.

In the period 301, REPAIREN[0] and REPAIR[0] and REPAIREN[1] and REPAIR [1] are all 1, so the third enable signal DEC_EN is low, and the function of the word line decoding module 204 is turned off.

Further, when REPAIREN[0] and REPAIR[0] and REPAIREN[1] and REPAIR [1] are turned on simultaneously, referring to FIG. 3:

In the period 301, ending of turning on of a repair region word line signal, namely, a fourth enable signal RES_CSTN causes turning off of a repair word line module 107, and repair_WL[0] and repair_WL[1] are turned off.

In addition, a signal CMUX_DIS, namely, a fifth enable signal CMUX_DIS, is turned on. The fifth enable signal CMUX_DIS turns off a transmission function of COLUMN _ MUX of SRAM IP, namely, a column multiplexer 202, via controlling of a CMUX_PASS signal.

In addition, a signal SA_DIS, namely, a sixth enable signal SA_DIS, is turned on. a SENSE_AMPLIFILER module is turned off by controlling a sense amplifier enable signal SA_EN (that is, a sense amplifier 203 is turned off), so that IP DQ output is protected and Q output is not changed.

Hereinafter, a working process of an embodiment of this application is further described in detail in combination with two repairs:

During a first repair, a BIST module 103 tests and feeds back that a failing address of a bitcell, namely, an address of a failed cell, is A[0: 13]=00000101010101. For this address, its higher ROW address is registered as RA_0[0: 9]=0101010101. An enable signal RRE[0] is equivalent to a signal REPAIREN[0] of SRAM IP, with RRE [0]=REPAIREN[0]=1. During a read/write operation, when a Row address of the read/write operation, namely A[4: 13], is the same as a registered failing address RA_0[0: 9] detected and fed back by the BIST module 103, a signal REPAIR[0] of the SRAM IP is pulled up.

During a second repair, the BIST module 103 tests and feeds back that a failing address of a feedback bitcell is A[0: 13]=11111010101010. For this address, its higher row address is registered as RA_1[0: 9]= 1010101010. When it is determined through detection that RA_1[0: 9] is different from an addresses of RA_0[0: 9], with RRE[1]=REPAIREN[1]=1. During a read/write operation, a ROW address A[4:13] for the read/write operation is the same as the registered failing address RA_1[0: 9] detected and fed back by the BIST module 103, a signal REPAIR[1] of SRAM IP is pulled up.

When the Row address A[4: 13] for the read/write operation is different from the registered failing addresses RA_[0: 9] and RA_1[0: 9] detected and fed back by the BIST module 103, reading/writing is directed to a normal Row, namely, a memory Row in a memory array 201.

A repair address mapping module 102 is mounted as a soft_core outside the SRAM IP through digital integration. During a repair process, based on a failure situation fed back by the BIST module 103, 1 repair or 2 repairs may be selected through settings.

This application is described in detail above with reference to specific embodiments, but these are not intended to limit this application. Those skilled in the art may make many variations and modifications without departing from the principle of this application. The variations and modifications should also be included in the scope of this application.

What is claimed is:

1. A static random access memory (SRAM) repair circuit, comprising: a row redundancy array module, a built-in self-test (BIST) module, a repair address mapping module, and a repair address control module, wherein
the row redundancy array module comprises a plurality of redundancy memory rows, and a structure of each of the redundancy memory rows is the same as a structure of each of memory rows in a memory array of an SRAM;
the BIST module is configured to detect whether the memory array has failed cells and output failing addresses corresponding to the failed cells when the failed cells are present;
the repair address mapping module is configured to register each of the failing addresses, provide a first enable signal, and achieve controlling of turning on of a repair function and control address mapping;
the repair address mapping module controls turning on and turning off of the repair function through the first enable signal and obtains the address mapping through the failing address; and the first enable signal comprises a plurality of bits, and the repair function is turned off when each of the signal bits of the first enable signal is disabled;
the repair address mapping module compares a read-write operation address and the failing address when at least one signal bit of the first enable signal is enabled, maps a read-write operation to the row redundancy array module when the read-write operation address and the failing address are the same to turn on the repair function, and maps the read-write operation to the memory array when the read-write operation address and the failing address are different; and
the repair address control module is configured to control strobing and turning off of each of the redundancy memory rows of the row redundancy array module through a second enable signal and a repair row selection signal when the repair function is turned on.

2. The SRAM repair circuit according to claim 1, wherein the quantity of signal bits of the second enable signal is the same as the quantity of signal bits of the repair row selection signal;
signal bits of the second enable signal and signal bits of the repair row selection signal having the same bit sequence numbers form a repair address control signal set, and the repair address control signal set controls strobing and turning off of one of the redundancy memory rows;
the second enable signal is obtained through the first enable signal;
one failing address corresponds to a signal bit of one repair row selection signal; and
when a signal bit of the second enable signal of the repair address control signal set is enabled and when the read-write operation address and a corresponding failing address are the same, a signal bit of the repair row selection signal of the repair address control signal set is switched to a strobing level and enables a controlled redundancy memory row to be strobed.

3. The SRAM repair circuit according to claim 2, wherein one of the failing addresses corresponds to a signal bit of one of the first enable signals; and
when the BIST module detects the failing address, a signal bit of the first enable signal corresponding to the failing address is enabled.

4. The SRAM repair circuit according to claim 3, further comprising a repair function fool-proof protection module;
the repair function fool-proof protection module is configured to provide a third enable signal, and the third enable signal is connected to a word line decoding module; and
when the repair row selection signal selects at least one of the redundancy memory rows, the third enable signal is enabled and causes the word line decoding module to be turned off.

5. The SRAM repair circuit according to claim 4, wherein the repair row selection signal is connected to a repair word line of each of the redundancy memory rows through a repair word line module;
the repair function fool-proof protection module is further configured to provide a fourth enable signal, and the fourth enable signal is connected to the repair word line module; and
when the repair row selection signal selects more than two of the redundancy memory rows, the fourth enable signal is enabled and causes the repair word line module to be turned off.

6. The SRAM repair circuit according to claim 5, wherein the repair function fool-proof protection module is further configured to provide a fifth enable signal, and
the fifth enable signal is connected to a column multiplexer, and the fifth enable signal causes the column multiplexer to be turned off when the repair row selection signal selects more than two of the redundancy memory rows.

7. The SRAM repair circuit according to claim 6, wherein the repair function fool-proof protection module is further configured to provide a sixth enable signal, and
the sixth enable signal is connected to a sense amplifier, and the sixth enable signal causes the sense amplifier to be turned off when the repair row selection signal selects more than two of the redundancy memory rows.

8. The SRAM repair circuit according to claim 4, wherein the repair address control module further outputs a seventh enable signal, the seventh enable signal is connected to the repair function fool-proof protection module, and when the repair function is turned on, the seventh enable signal activates the repair function fool-proof protection module.

9. The SRAM repair circuit according to claim 5, wherein the quantity of bits of the repair row selection signal is the same as the quantity of rows of the redundancy memory row, and bits of the repair row selection signal correspond to the redundancy memory rows one by one.

10. The SRAM repair circuit according to claim 9, wherein
the repair address mapping module further comprises a function of performing repeatability detection on the failing address, and
the repeatability detection comprises: during the k-th repair, the repair address mapping module determines whether a failing address for the k-th repair is the same as each of failing addresses of previous k-1 repairs, wherein if a case that they are identical exists, a signal bit of a first enable signal corresponding to the failing address for the k-th repair kept being disabled, if a case that they are identical does not exist, the signal bit of the first enable signal corresponding to the failing address for the k-th repair kept being enabled, and k is a quantity of rows greater than 1 and less than or equal to the redundancy memory rows.

11. The SRAM repair circuit according to claim 10, wherein when the signal bit of the first enable signal is enabled, a signal bit corresponding to the second enable signal is also enabled, and when the signal bit of the first enable signal is disabled, the signal bit corresponding to the second enable signal is also disabled;
the second enable signal is connected to the repair word line module;
when the signal bit of the second enable signal of the repair address control signal set is enabled, a signal bit of the repair row selection signal of the repair address control signal set is connected to a corresponding repair word line; and
when the signal bit of the second enable signal of the repair address control signal set is disabled, the signal bit of the repair row selection signal of the repair address control signal set is disconnected from a corresponding repair word line.

12. The SRAM repair circuit according to claim 11, wherein the failing address is a row address of the failed cell, the repair address mapping module compares the read-write operation address with the failing address, and for repair, a by-row repair is adopted;
or the failing address is an entire address of the failed cell, the repair address mapping module uses an entire address of the read-write operation address for comparison with the failing address when comparing the read-write operation address with the failing address, and for the repair, a by-word repair is adopted.

13. The SRAM repair circuit according to claim 2, wherein the strobing level is high and non-strobing level is low, or the strobing level is low and the non-strobing level is high.

14. The SRAM repair circuit according to claim 11, wherein the signal bit of the first enable signal is enabled at a high level and disabled at a low level, or the signal bit of the first enable signal is enabled at a low level and disabled at a high level; and
the signal bit of the second enable signal is enabled at a high level and disabled at a low level; or, the signal bit of the second enable signal is enabled at a low level and disabled at a high level.

15. The SRAM repair circuit according to claim 1, wherein the row redundancy array module is a repair data memory region within an SRAM IP.

16. The SRAM repair circuit according to claim 1, wherein the BIST module tests all values covered by an addressing range of the SRAM; and
the BIST module is embedded in the SRAM and as part of SRAM IP; or, the BIST module is mounted as a soft-core outside the SRAM IP.

17. The SRAM repair circuit according to claim 1, wherein the repair address mapping module is embedded in the SRAM and is part of SRAM IP; or the repair address mapping module is mounted as a soft-core outside the SRAM IP.
